(19) United States
(12) Patent Application Publication
(10) Pub. No.: US 2026/0221393 A1
(43) Pub. Date: Jul. 30, 2026

(54) LOCAL ETCHING APPARATUS

(71) Applicant: SAMSUNG ELECTRONICS CO., LTD., Suwon-si (KR)

(72) Inventors: Hohyun LEE, Suwon-si (KR); Sungho JANG, Suwon-si (KR); Donghoon KWON, Suwon-si (KR); Wonguk SEO, Suwon-si (KR); Young YOON, Suwon-si (KR); Sungyong LIM, Suwon-si (KR); Jinoh IM, Suwon-si (KR); Sungwon CHO, Suwon-si (KR)

(73) Assignee: SAMSUNG ELECTRONICS CO., LTD., Suwon-si (KR)

(21) Appl. No.: 19/407,627

(22) Filed: Dec. 3, 2025

(30) Foreign Application Priority Data
Jan. 24, 2025 (KR) 10-2025-0011901

(51) Int. Cl. H01J 37/32

(52) U.S. Cl. CPC H01J 37/32522; H01J 37/3244; H01J 2237/334; H10P 72/0421

(57) ABSTRACT

A local etching apparatus includes a plasma nozzle jetting plasma particles toward an etching region, which is a portion of an entire region of an upper surface of a target and a light heating module projecting a region-heating light toward a light projection region which is a portion of the entire region of the upper surface of the target, wherein the light heating module includes a laser light source outputting a pulsed laser light and a spatial light modulator receiving the pulsed laser light, modulating the pulsed laser light, and outputting the region-heating light, and wherein the light projection region includes the etching region.

### CROSS-REFERENCE TO RELATED APPLICATION

This application is based on and claims priority under 35 USC § 119 to Korean Patent Application No. 10-2025-0011901, filed on Jan. 24, 2025, in the Korean Intellectual Property Office, the disclosure of which is incorporated by reference herein in its entirety.

### BACKGROUND

The inventive concept relates to a local etching apparatus, and more particularly, to a local etching apparatus including a plasma nozzle.

To flatten surfaces of wafers, a polishing process may be performed on wafers. However, even after the polishing process is performed, a plurality of irregularities may remain on surfaces of wafers. Due to the plurality of remaining irregularities, surfaces of the wafer may be uneven, and the thickness of the wafer may not be uniform throughout.

An uneven thickness of the wafer may have a negative impact on subsequent semiconductor manufacturing processes. Accordingly, there is a growing need for a method of forming wafers with a uniform thickness throughout by removing a plurality of irregularities remaining on surfaces of wafers.

### SUMMARY

The inventive concept provides a local etching apparatus capable of manufacturing a wafer having a uniform thickness over the entire area.

The inventive concept also provides a local etching apparatus having ultra-precision spatial resolution.

However, the problems to be solved by the inventive concept are not limited to the problems mentioned above, and other problems may be clearly understood by those skilled in the art from the description below.

According to an aspect of the inventive concept, there is provided a local etching apparatus including a plasma nozzle jetting plasma particles toward an etching region, which is a portion of an entire region of an upper surface of a target and a light heating module projecting a region-heating light toward a light projection region which is a portion of the entire region of the upper surface of the target, wherein the light heating module includes a laser light source outputting a pulsed laser light and a spatial light modulator receiving the pulsed laser light, modulating the pulsed laser light, and outputting the region-heating light, and wherein the light projection region includes the etching region.

According to another aspect of the inventive concept, there is provided a local etching apparatus including a plasma nozzle jetting plasma particles toward an upper surface of a target, a light heating module projecting a region-heating light toward the upper surface of the target, and a stage on an upper surface of which the target is placed, wherein the light heating module includes a laser light source and a spatial light modulator receiving pulsed laser light output from the laser light source, modulating the pulsed laser light, and outputting the region-heating light

According to another aspect of the inventive concept, there is provided a local etching apparatus including a plasma nozzle jetting plasma particles toward an upper surface of a target, a light heating module projecting a region-heating light toward the upper surface of the target, a stage on an upper surface of which the target is supported, the stage driving the target in a horizontal direction, and a controller configured to store target etching depth information on the upper surface of the target, wherein the controller is configured to divide the upper surface of the target into a plurality of etching regions, based on a jet width of the plasma particles, identify a plurality of target etching depth distributions respectively for the plurality of etching regions, based on the target etching depth information, identify a plurality of target light intensity distributions respectively corresponding to the plurality of etching regions, based on the plurality of target etching depth distributions, and control the stage and the light heating module such that a plurality of beams of region-heating light having the plurality of target light intensity distributions respectively corresponding to the plurality of etching regions are projected to the plurality of etching regions, and wherein each of the plurality of etching regions is a region in which etching of the target is performed by the plurality of beams of region-heating light and the plasma particles.

### BRIEF DESCRIPTION OF THE DRAWINGS

Embodiments will be more clearly understood from the following detailed description taken in conjunction with the accompanying drawings in which:

FIG. 1 is a cross-sectional view of a local etching apparatus according to an embodiment;

FIG. 2 is a flowchart illustrating a local etching method of a local etching apparatus, according to an embodiment;

FIG. 3 is a cross-sectional view illustrating a local etching apparatus according to an embodiment;

FIG. 4 is a cross-sectional view illustrating an etching region and a light projection region, according to an embodiment;

FIG. 5 is a flowchart illustrating a local etching method of a local etching apparatus, according to an embodiment;

FIG. 6 is a cross-sectional view illustrating an etching region according to an embodiment;

FIG. 7 is a cross-sectional view illustrating a spatial light modulator according to an embodiment;

FIG. 8 is a cross-sectional view illustrating an etching region and a light projection region, according to an embodiment;

FIG. 9 is a cross-sectional view illustrating an etching region according to an embodiment;

FIG. 10 is a flowchart illustrating a local etching method of a local etching apparatus, according to an embodiment;

FIG. 11 is a cross-sectional view illustrating a local etching apparatus according to an embodiment;

FIG. 12 is a flowchart illustrating a local etching method of a local etching apparatus, according to an embodiment;

FIG. 13 is a cross-sectional view of a target according to an embodiment; and

FIG. 14, FIG. 15A, FIG. 15B, FIG. 16A and FIG. 16B are cross-sectional views illustrating a wafer manufacturing method of a local etching apparatus, according to an embodiment.

### DETAILED DESCRIPTION OF THE EMBODIMENTS

Hereinafter, embodiments are described in detail with reference to the accompanying drawings. Like reference numerals denote like components in the drawings, and redundant descriptions thereof are omitted.

Herein, a horizontal direction may include a first horizontal direction (an X direction) and a second horizontal direction (a Y direction) that intersect each other. A direction that intersects the first horizontal direction (the X direction) and the second horizontal direction (the Y direction) may be referred to as a vertical direction (a Z direction). Herein, a vertical level may be referred to as a height level of a component in the vertical direction (the Z direction).

Hereinafter, embodiments are described clearly and in detail to such an extent that a person skilled in the art may easily practice the inventive concept.

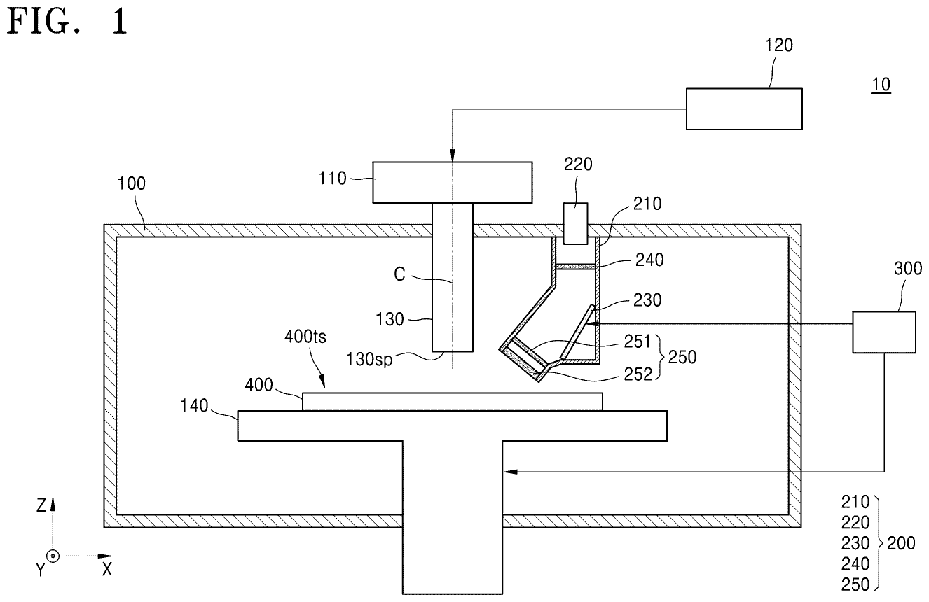

FIG. 1 is a cross-sectional view of a local etching apparatus 10 according to an embodiment.

Referring to FIG. 1, the local etching apparatus 10 may include a housing 100, a plasma generating device 110, a gas source 120, the plasma nozzle 130, a stage 140, a light heating module 200, and a controller 300.

The housing 100 may limit a space in which a local etching process is performed and seal the space from the outside. An internal space of the housing 100 may be maintained in a vacuum state. The housing 100 may have a cylindrical shape. The housing 100 may include a metal material and may also include an insulating material, such as ceramic or quartz.

The plasma generating device 110 may generate plasma. Plasma particles (e.g., ions, radicals) generated inside the plasma generating device 110 may be supplied toward the plasma nozzle 130. The plasma generating device 110 may receive an etching gas from a gas source 120 and discharge the etching gas supplied from the gas source 120. Plasma may be generated by discharging the etching gas. For example, when the etching gas is chlorine gas Cl₂, the plasma generating device 110 may discharge the chlorine gas Cl₂, and plasma including particles, such as chlorine ions Cl⁺ and chlorine radicals Cl*, may be generated by the discharge of chlorine gas Cl₂. The above description is only an example presented for convenience of description, and the types of etching gas and plasma particles generated by the discharge of the etching gas may be diverse.

According to an embodiment, the plasma generating device 110 may be a microwave plasma source. In this case, the plasma generating device 110 may include a microwave generating device (e.g., a magnetron) and a waveguide. The microwave generating device may generate microwaves, and the waveguide may guide the propagation of the generated microwaves. Inside the plasma generating device 110, an etching gas may be discharged by microwaves.

However, the aforementioned example is only an example of the type of plasma generating device 110, and the plasma generating device 110 may be implemented with various types of plasma sources. For example, the plasma generating device 110 may be implemented as a DC plasma source, an RF plasma source, a dielectric barrier discharge (DBD) plasma source, etc. and may be various types of devices capable of supplying plasma particles (e.g., ions, radicals) toward the plasma nozzle 130.

The plasma nozzle 130 may be inserted from the outside of the housing 100 into the inside of the housing 100 by penetrating a portion of an upper surface of the housing 100. The plasma nozzle 130 may have a cylindrical shape. The plasma nozzle 130 may be connected to the plasma generating device 110 and may receive plasma particles from the plasma generating device 110.

The plasma nozzle 130 may include a spray port 130sp formed on a lower surface of the plasma nozzle 130. The spray port 130sp may face an upper surface 400ts of a target 400. The spray port 130sp may be a hole formed on the lower surface of the plasma nozzle 130. The plasma nozzle 130 may jet plasma particles toward the upper surface 400ts of the target 400 through the spray port 130sp.

The plasma nozzle 130 may jet plasma particles toward an etching region, which is a portion of the entire area of the upper surface 400ts of the target 400. Here, the etching region may refer to a region of the target on which etching is performed by plasma particles jetted from the plasma nozzle 130. The etching region may be a region having an area of about 0.1% to 2% of the total area of the upper surface 400ts of the target 400. For example, if the upper surface 400ts of the target 400 is a circular plate having a diameter of 300 mm, the etching region may be a circular region having a diameter of 20 mm.

The stage 140 may support the target 400. The target 400 may be fixed to the upper surface of the stage 140. The stage 140 may be placed inside the housing 100. The stage 140 may drive the target 400 in the horizontal direction (the X and Y directions). The target 400 may be driven in the horizontal direction by the stage 140, and the etching region may move within the entire region of the upper surface 400ts of the target 400. In an embodiment, the target 400 is driven in the horizontal direction by the stage 140, while the plasma nozzle 130 is not driven in the horizontal direction but is fixed, and thus, the region of the upper surface 400ts of the target 400 facing the spray port 130sp may change. Accordingly, a local etching process may be performed on the entire region of the upper surface 400ts of the target 400.

Although not illustrated in detail in FIG. 1, the stage 140 may include a horizontal (the X-Y direction) motor that drives the stage 140 in a horizontal direction and a vertical (the Z direction) motor that drives the stage 140 in a vertical direction.

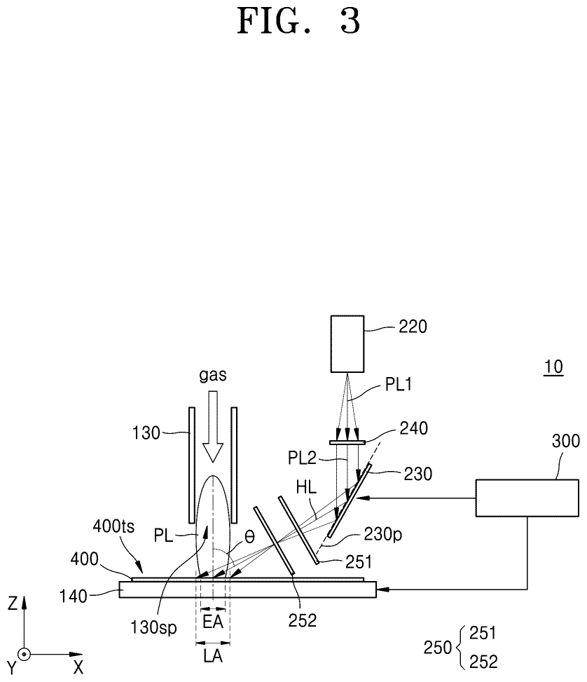

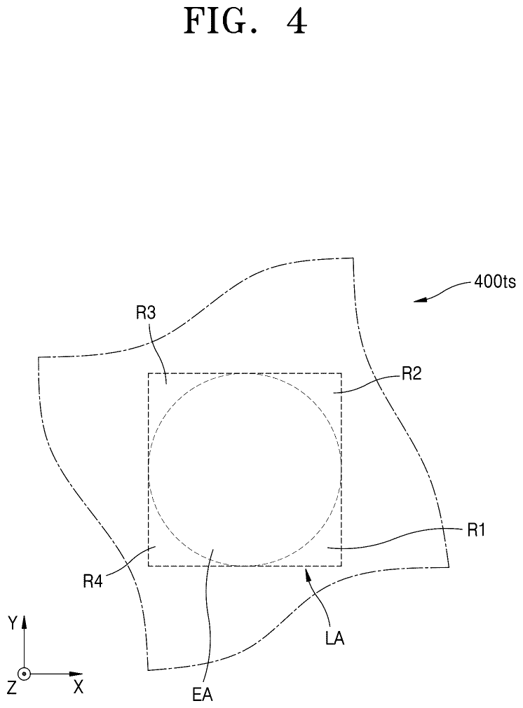

The light heating module 200 may project region-heating light toward the upper surface 400ts of the target 400. In the inventive concept, the region-heating light may refer to light projected onto a partial region of the entire region of the upper surface 400ts of the target 400 to heat the partial region. In addition, in the inventive concept, a partial region of the upper surface 400ts onto which region-heating light is projected is referred to as a light projection region. The light projection region may include an etching region. The light projection region and etching region are described in detail in the description of FIGS. 3 and 4 below.

The light heating module 200 may include a module housing 210, a laser light source 220, a spatial light modulator 230, an illumination optical system (or illumination optics) 240, and a projection optical system (or projection optics) 250.

The module housing 210 may configure the overall appearance of the light heating module 200. The laser light source 220, the spatial light modulator 230, the illumination optical system 240, and the projection optical system 250 may be placed inside the module housing 210. The module housing 210 may isolate the laser light source 220, the spatial light modulator 230, the illumination optical system 240, and the projection optical system 250 from the external environment and protect them from external contamination and impact.

The laser light source 220 may output pulsed laser light toward the spatial light modulator 230. In the inventive concept, pulsed laser light may refer to laser light having a very short duration. For example, the duration of pulsed laser light may be from several femtoseconds (fs) to hundreds of fs. As another example, the duration of pulsed laser light may be from several picoseconds (ps) to hundreds of ps. In addition, the pulsed laser light may be light including at least one of ultraviolet (UV) rays, extreme ultraviolet (EUV) rays, X-ray, visible light, and infrared (IR) rays.

Because the laser light source 220 outputs pulsed laser light in a pulse form, a phenomenon of temperature rising in other regions of the target 400 that do not require light heating may be prevented as much as possible. In particular, because the duration of the pulsed laser light may be implemented as several fs to several hundred fs, a phenomenon of heat being conducted to a region of the target 400 in which light is not projected may be prevented.

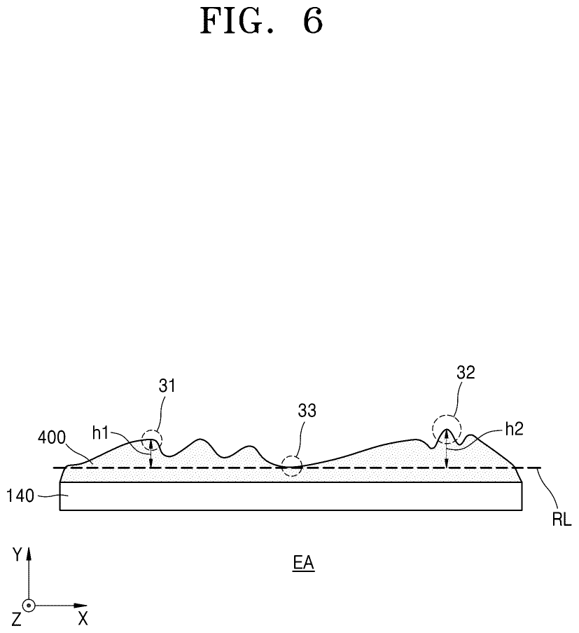

The spatial light modulator 230 may receive pulsed laser light, modulate the pulsed laser light, and output region-heating light. In an embodiment, the spatial light modulator 230 may modulate the pulsed laser light and output region-heating light to project region-heating light having a target light intensity distribution onto the light projection region. Here, the target light intensity distribution may refer to a light intensity distribution that the region-heating light has to have for precise etching of the etching region. In an embodiment, the target light intensity distribution may correspond to a target etching depth distribution for an etching region, and the target etching depth distribution may refer to distributions of a plurality of target etching depths respectively for a plurality of points included in the etching region. The target light intensity distribution and the target etching depth distribution are described in detail with reference to FIG. 6 below.

The spatial light modulator 230 may be implemented as a digital micromirror device (DMD) or a liquid crystal on silicon device (LCoS). However, without being limited to the aforementioned examples, the spatial light modulator 230 may be implemented as a deformable mirror, an optical grating, a diffraction optical element, etc.

The illumination optical system 240 may transmit pulsed laser light output from the laser light source 220 to the spatial light modulator 230. The illumination optical system 240 may include at least one lens, as illustrated in FIG. 1. For example, at least one lens included in the illumination optical system 240 may collimate pulsed laser light and transmit the collimated light to the spatial light modulator 230.

As another example, the illumination optical system 240 may further include a polarizer placed in a traveling path of the pulsed laser light. The polarizer included in the illumination optical system 240 may allow pulsed laser light having only a certain polarization state to pass therethrough and be transmitted to the spatial light modulator 230. The illumination optical system 240 may further include various components for transmitting pulsed laser light from the laser light source 220 toward the spatial light modulator 230, such as further including a phase delay plate, mirrors, etc.

The projection optical system 250 may project region-heating light output from the spatial light modulator 230 onto the upper surface 400ts of the target 400. In an embodiment, the projection optical system 250 may project region-heating light onto a light projection region that is a portion of the entire region of the upper surface 400ts. The projection optical system 250 may include a polarizer 251 and at least one lens 252.

The polarizer 251 of the projection optical system 250 may receive region-heating light output from the spatial light modulator 230 and may allow only region-heating light having a certain polarization state to pass therethrough. For example, the polarizer 251 may allow only an electric field component vibrating in a certain direction among electric field components of the region-heating light and block an electric field component vibrating in a direction orthogonal to the certain direction.

The at least one lens 252 of the projection optical system 250 may transmit region-heating light passing through the polarizer 251 to the upper surface 400ts of the target 400. For example, the at least one lens 252 may appropriately magnify or reduce the region-heating light output from the spatial light modulator 230 and transmit the same to the upper surface 400ts of the target 400. As another example, the at least one lens 252 may transmit the region-heating light to the upper surface 400ts of the target 400 without magnifying or reducing the region-heating light.

The above description merely illustrates the configuration and arrangement of the projection optical system 250 according to an embodiment, and the projection optical system 250 may not include the polarizer 251 or may further include a phase retardation plate, a mirror, etc. That is, the projection optical system 250 may include various components for transmitting region-heating light from the spatial light modulator 230 toward the upper surface 400ts of the target 400.

The controller 300 may be operatively connected to the spatial light modulator 230 and the stage 140 and may control the overall operations of the local etching apparatus 10. The controller 300 may be implemented in hardware, firmware, software, or any combination thereof. For example, the controller 300 may include a computing device, such as a workstation computer, a desktop computer, a laptop computer, or a tablet computer. The controller 300 may include a complex processor, such as a microprocessor, a CPU, a GPU, a processor configured by software, dedicated hardware, or firmware. The controller 300 may be implemented by, for example, a general-purpose computer or application-specific hardware, such as a digital signal processor (DSP), a field programmable gate array (FPGA), and an application specific integrated circuit (ASIC). The controller 300 may be implemented as instructions stored on a machine-readable medium that may be read and executed by at least one processor. Here, the machine-readable medium may include any mechanism for storing and/or transmitting information in a form readable by a machine (e.g., a computing device). For example, the machine-readable medium may include read only memory (ROM), random-access memory (RAM), magnetic disk storage medium, optical storage medium, flash memory devices, electrical, optical, acoustical or other forms of radio signals (e.g., carrier waves, infrared signals, digital signals, etc.), and any other signals.

According to an embodiment, the controller 300 may store target etching depth information on the upper surface 400ts of the target 400 and region-specific driving speed information of the target 400 by the stage 140. The controller 300 may identify a target light intensity distribution for an etching region based on the target etching depth information. In addition, the controller 300 may identify the target light intensity distribution for the etching region based on the target etching depth information and region-specific driving speed information. The method of the controller 300 identifying the target light intensity distribution is described in detail with reference to the accompanying drawings.

The controller 300 may control the stage 140 such that the target 400 may be driven with a velocity profile corresponding to the region-specific driving speed information. For example, the controller 300 may control the stage 140 such that the target 400 may be driven at a speed of 3 mm/s in the +X direction when the spray port 130sp faces a first region of the target 400 and may control the stage 140 such that the target 400 may be driven at a speed of 2 mm/s in the +Y direction when the spray port 130sp faces a second region of the target 400.

The controller 300 may control the spatial light modulator 230 such that region-heating light having the target light intensity distribution may be projected onto the upper surface 400ts of the target 400. For example, the controller 300 may identify a plurality of phase modulation values and/or a plurality of amplitude modulation values to be applied respectively to a plurality of light modulation pixels included in the spatial light modulator 230 and may apply the plurality of phase modulation values and/or the plurality of amplitude modulation values to the plurality of light modulation pixels, respectively.

The target 400 may be a material that is subject to a local etching process performed by the local etching apparatus 10. For example, the target 400 may be a wafer. However, the target 400 is not limited to a wafer, and the target 400 may be implemented with various materials that require local etching.

The local etching apparatus 10 may include the components described above, thereby improving the spatial resolution of the local etching process for the target 400. In an embodiment, if the local etching apparatus 10 does not include the light heating module 200, an etching process may be performed only based on plasma particles jetted from the spray port 130sp of the plasma nozzle 130 to the upper surface 400ts of the target 400 in the vertical direction. In this case, the etching process may be performed by the same/similar etching depth for a plurality of points included within the etching region of the upper surface 400ts. However, because the local etching apparatus 10 includes the light heating module 200, the etching process may be performed by different etching depths respectively for a plurality of points included in the etching region. Here, in the etching region, etching may be performed on the target 400, based on plasma particles jetted from the plasma nozzle 130 and region-heating light output from the light heating module 200.

In an embodiment, as the temperature of the target 400 increases, an etching rate of the etching process for the target 400 may increase. Therefore, the light heating module 200 may heat each of the plurality of points to a different target temperature, thereby setting the etching rate of the etching process for each of the plurality of points to be different from each other. The etching process for the target 400 performed based on plasma particles and region-heating light is described in detail below.

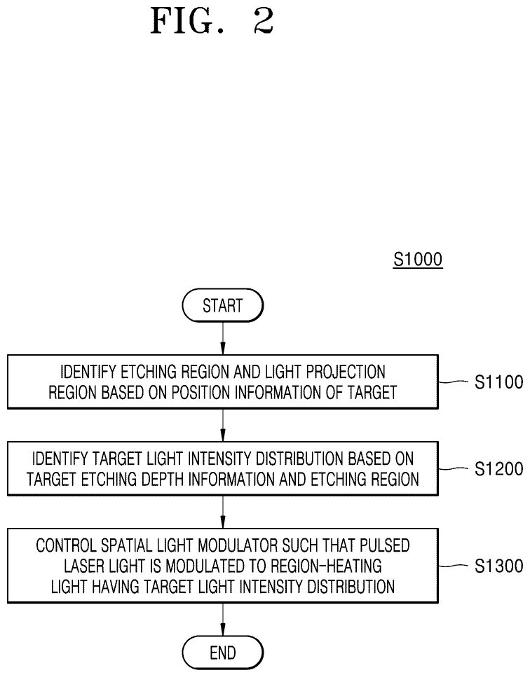

FIG. 2 is a flowchart illustrating a local etching method (S1000) of the local etching apparatus 10, according to an embodiment. Descriptions are given with reference to FIG. 2 together with FIG. 1.

Referring to FIG. 2, the local etching apparatus 10 may identify an etching region and a light projection region, based on position information of the target 400 (S1100, hereinafter referred to as a first operation).

According to an embodiment, in the first operation, the controller 300 may obtain the position information of the target 400 from the stage 140. The controller 300 may obtain relative position information on the plasma nozzle 130 of the target 400 from the stage 140. In a default state, the center axes of the stage 140, target 400, and plasma nozzle 130 may all be aligned to the same horizontal coordinates (XY coordinates). Here, the plasma nozzle 130 is fixed, while the stage 140 and the target 400 are driven in the horizontal direction, so the relative position of the target 400 with respect to the plasma nozzle 130 may be determined by the horizontal driving of the target 400 by the stage 140. For example, when the target 400 is driven by the stage 140 by 10 mm in the +X direction from the default state, the center axis of the target 400 may be positioned at a position apart by 10 mm in the +X direction from the center axis C of the plasma nozzle 130. In this case, the controller 300 may obtain information on the driving amount and driving direction of the target 400 from the stage 140 as the position information of the target 400.

In the aforementioned example, the state in which the center axes of the stage 140, the target 400, and the plasma nozzle 130 are aligned is defined as the default state, but this is only an example, and it is obvious that the default state may be defined based on various methods. In addition, the method of the controller 300 obtaining the position information of the target 400 is not limited to the aforementioned example, and the controller 300 may obtain the position information of the target 400, based on various methods.

According to an embodiment, in the first operation, the controller 300 may identify the etching region and the light projection region based on the position information of the target 400. The controller 300 may identify the relative position of the target 400 with respect to the plasma nozzle 130, based on the position information of the target 400, and may identify the etching region based on the relative position. In addition, the controller 300 may identify the relative position of the target 400 with respect to the light heating module 200, based on the position information of the target, and may identify the light projection region based on the relative position. The method of the controller 300 identifying the etching region and the light projection region is described in detail with reference to FIG. 3 below.

The local etching apparatus 10 may identify the target light intensity distribution based on the target etching depth information and the etching region (S1200, hereinafter referred to as the second operation).

According to an embodiment, the controller 300 may store target etching depth information on the entire region of the upper surface 400ts of the target 400. The target etching depth information on the entire region of the upper surface 400ts of the target 400 may include target etching depths for each of all points included in the upper surface 400ts of the target 400. For example, the controller 300 may obtain the target etching depth information based on an image of the upper surface 400ts. The controller 300 may identify a plurality of irregularities on the upper surface 400ts, based on the image of the upper surface 400ts, calculate target etching depths for removing the plurality of irregularities, and store the calculated target etching depths as target etching depth information.

Here, the image of the upper surface 400ts may be a 3D image. However, the image of the upper surface 400ts is not limited to a 3D image and may be various types of images. In addition, the target etching depth information stored by the controller 300 is described in detail with reference to FIG. 6 below.

According to an embodiment, in the second operation, the controller 300 may identify a target etching depth distribution for the etching region, based on the target etching depth information. For example, the controller 300 may identify the target etching depth distribution for the etching region by extracting only information corresponding to the etching region, which is a portion of the entire region of the upper surface 400ts of the target 400, from the target etching depth information. Here, the target etching depth distribution may include a plurality of points included in the etching region and target etching depths respectively mapped to the plurality of points.

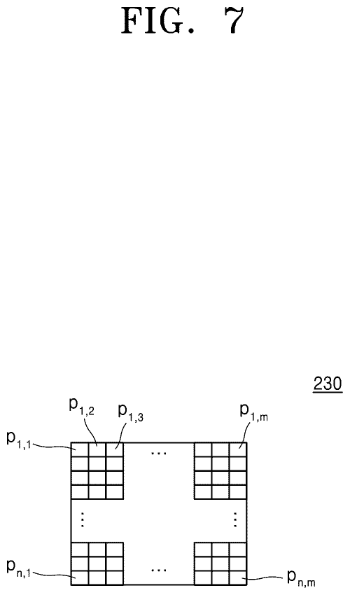

According to an embodiment, in the second operation, the controller 300 may identify a target light intensity distribution for the light projection region, based on the target etching depth distribution for the etching region. In an example, the controller 300 may identify a target light intensity distribution such that, among the plurality of points existing in the etching region, the light intensity of region-heating light projected on a point of a first target etching depth (a point with a high target etching depth) has a greater value than the light intensity of region-heating light projected on a point of a second target etching depth (a point with a low target etching depth). In addition, the controller 300 may identify a target light intensity distribution that makes the light intensity of region-heating light projected to a region excluding the etching region among the light projection regions substantially 0 (zero value). The method of the controller 300 identifying the target light intensity distribution is described in detail with reference to FIGS. 7 to 11 below.

The local etching apparatus 10 may control the spatial light modulator 230 such that pulsed laser light is modulated into region-heating light having a target light intensity distribution (S1300, hereinafter referred to as a third operation).

According to an embodiment, in the third operation, the controller 300 may assign a plurality of light modulation values respectively to a plurality of light modulation pixels included in the spatial light modulator 230.

The local etching method (S1000) of the local etching apparatus 10 according to one or more embodiments may include the first operation (S1100), the second operation (S1200), and the third operation (S1300), thereby enabling respective etching rates for the plurality of points included in the etching region to be set to be different from each other. For example, the etching process according to the local etching method (S1000) may have a high etching rate for a point at which a large etching depth is required compared to other points among the plurality of points included in the etching region and may have a low etching rate for a point at which a low etching depth is required compared to other points among the plurality of points included in the etching region. The process in which plasma particles are jetted and the process in which region-heating light is projected with respect to the upper surface 400ts of the target 400 are described in detail with reference to FIG. 3.

FIG. 3 is a cross-sectional view illustrating the local etching apparatus 10 according to an embodiment.

Referring to FIG. 3, plasma particles PL jetted from the plasma nozzle 130 may be jetted to an etching region EA, which is a portion of the entire region of the upper surface 400ts of the target 400. In addition, region-heating light HL may be projected onto a light projection region LA, which is a portion of the entire region of the upper surface 400ts of the target 400.

According to an embodiment, the plasma particles PL may be jetted in a direction perpendicular to the upper surface 400ts of the target 400 as a whole. As described above with reference to FIG. 1, the plasma particles PL may be provided from the plasma generating device 110 toward the plasma nozzle 130. As illustrated in FIG. 3, the plasma particles PL may move toward the spray port 130sp of the plasma nozzle 130 along the flow of gas from top to bottom, and the plasma particles PL moved toward the spray port 130sp may be jetted in a downward direction.

The plasma particles PL may include radical particles and ion particles, and the plasma particles PL may physically and/or chemically etch the upper surface 400ts of the target 400. For example, etching of the target 400 performed based on plasma particles PL may be reactive ion etching.

The laser light source 220 may output a first pulsed laser light PL1 in the downward direction. The illumination optical system 240 may receive the first pulsed laser light PL1 and transmit a second pulsed laser light PL2 to the spatial light modulator 230. Here, the second pulsed laser light PL2 may refer to the first pulsed laser light PL1 which has been collimated.

According to an embodiment, as illustrated in FIG. 3, the spatial light modulator 230 may be a reflective spatial light modulator. The spatial light modulator 230 may receive the second pulsed laser light PL2, modulate the second pulsed laser light PL2, and output region-heating light HL. The spatial light modulator 230 may be positioned to be inclined with respect to a traveling direction (e.g., a −Z direction) of the second pulsed laser light PL2.

The region-heating light HL may be transmitted through the polarizer 251 of the projection optical system 250 to the at least one lens 252 of the projection optical system 250.

The projection optical system 250 may project the region-heating light HL onto the light projection region LA. The region-heating light HL may be projected onto the light projection region LA at an angle θ inclined with respect to the vertical direction.

According to an embodiment, the shape of an image formed by the region-heating light HL on a spatial light modulator plane (230p, hereinafter referred to as a spatial light modulator (SLM) plane) may be the same as the shape of an image formed by the region-heating light HL on the upper surface 400ts of the target 400. The SLM plane 230p may exist on a frontside of the spatial light modulator 230 and may be a virtual plane parallel to the spatial light modulator 230.

According to another embodiment, the projection optical system 250 may magnify the region-heating light HL and project the same onto the light projection region LA. In this case, the image formed by the region-heating light HL on the SLM plane 230p may be smaller than the image formed by the region-heating light HL on the upper surface 400ts.

The controller 300 may control the spatial light modulator 230 to modulate the second pulsed laser light PL2 and output the region-heating light HL. The region-heating light HL may be light modulated to have a target light intensity distribution in the light projection region LA.

According to an embodiment, the controller 300 may assign a plurality of light modulation values respectively to the plurality of light modulation pixels included in the spatial light modulator 230. For convenience of description, it is assumed that the spatial light modulator 230 is an LCOS device including a plurality of light modulation pixels, and the second pulsed laser light PL2 is linearly polarized. In this case, the plurality of light modulation pixels of the spatial light modulator 230 may be assigned a plurality of phase modulation values, respectively. The polarization state of the second pulsed laser light PL2 may be changed by each of the plurality of light modulation pixels of the spatial light modulator 230.

For example, among the plurality of light modulation pixels, a first light modulation pixel assigned a first phase modulation value may receive the second pulsed laser light PL2 of linear polarization and output the region-heating light HL of circular polarization, while a second light modulation pixel assigned a second phase modulation value may receive the second pulsed laser light PL2 of linear polarization and output the region-heating light HL of elliptical polarization.

In this case, the region-heating light HL output from the first light modulation pixel and the region-heating light HL output from the second light modulation pixel may have different polarization states. Accordingly, the region-heating light HL output from the first light modulation pixel and the region-heating light HL output from the second light modulation pixel may have different light intensity values, while passing through the polarizer 251 of the projection optical system 250.

As in the example described above, the controller 300 may assign different light modulation values respectively to the plurality of light modulation pixels of the spatial light modulator 230, thereby allowing beams of the region-heating light HL respectively output from the plurality of light modulation pixels to have different light intensity values. Here, the plurality of light modulation values may be respectively implemented as intensity values of an electric field respectively applied to the plurality of light modulation pixels.

However, the aforementioned example is only an example of the controller 300 controlling the spatial light modulator 230, and the controller 300 may control the spatial light modulator 230 to modulate the second pulsed laser light PL2 and output the region-heating light HL, based on various methods. For example, if the spatial light modulator 230 is a digital micromirror device (DMD), the controller 300 may assign a plurality of phase/amplitude modulation values (e.g., respective tilting angles of the plurality of micromirrors) respectively to the plurality of light modulation pixels (e.g., a plurality of micromirrors) of the spatial light modulator 230. In some embodiments, the polarizer 251 may be omitted.

As described above, plasma particles PL may be jetted in the vertical direction toward the upper surface 400ts of the target 400, and the region-heating light HL may be projected onto the upper surface 400ts at the angle θ inclined with respect to the vertical direction. Through this, heating and etching may be performed simultaneously on the etching region EA.

FIG. 4 is a cross-sectional view illustrating the etching region EA and the light projection region LA, according to an embodiment. FIG. 4 is a top view of the upper surface 400ts of the target 400.

Referring to FIG. 4, the light projection region LA may include the etching region EA.

The etching region EA may be a region that plasma particles PL jetted from the plasma nozzle 130 reach in the entire region of the upper surface 400ts. The light projection region LA may be a region within the entire region of the upper surface (400 ts) onto which the region-heating light HL is projected.

According to an embodiment, the light projection region LA may include the etching region EA and a non-etching region. For example, as illustrated in FIG. 4, the light projection region LA may be a wider region than the etching region EA. In this case, the non-etching region may be a region obtained by excluding the etching region EA from the light projection region LA.

According to an embodiment, the non-etching region may include a plurality of non-etching regions R1, R2, R3, and R4. As illustrated in FIG. 4, the etching region EA is a circular area, and the light projection region LA may be implemented as a square area that is in contact with the etching region EA. In this case, the non-etching region may include a first non-etching region R1, a second non-etching region R2, a third non-etching region R3, and a fourth non-etching region R4.

The non-etching region is a region in which etching is not performed and may not require heating by the region-heating light HL. Accordingly, the controller 300 may control the spatial light modulator 230 such that the light quantity of region-heating light HL projected onto the non-etching region becomes substantially 0 (zero value). Here, “the light quantity is practically zero” could mean that the light is projected at a very small light quantity compared to the light quantity projected onto the etching region EA. For example, if the light quantity projected onto a point included in the etching region EA is 10 W/cm², the light quantity projected onto the non-etching region may be 0.1 W/cm².

Although FIG. 4 illustrates the etching region EA as a circular region, this is only an example and the etching region EA may be implemented as a region of various shapes. For example, the etching region EA may be implemented as an elliptical or rectangular region. In addition, although FIG. 4 illustrates the light projection region LA as a square-shaped region, this is only an example, and the light projection region LA may also be implemented as a region of various shapes, such as a rectangular shape.

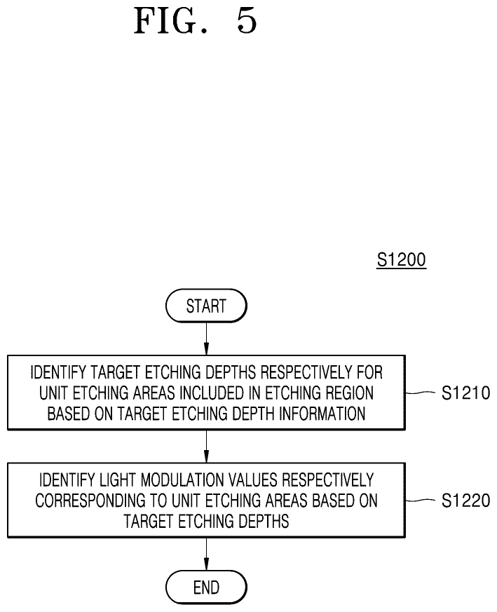

FIG. 5 is a flowchart illustrating a local etching method of the local etching apparatus 10, according to an embodiment. Descriptions are given with reference to FIG. 5 together with FIGS. 1 to 4.

Referring to FIG. 5, in the second operation (S1200), the local etching apparatus 10 may identify a plurality of target etching depths respectively for a plurality of unit etching areas included in the etching region EA, based on the target etching depth information (S1210).

According to an embodiment, the controller 300 may divide the etching region EA into a plurality of unit etching areas. As an example, the controller 300 may divide the etching region EA into a plurality of unit etching areas, based on the arrangement structure of the plurality of light modulation pixels included in the spatial light modulator 230 and the arrangement structure of the projection optical system 250. The method of the controller 300 dividing the etching region EA into a plurality of unit etching areas is described in detail with reference to FIGS. 7 to 9 below.

According to an embodiment, the controller 300 may identify the plurality of target etching depths respectively for the plurality of unit etching areas, based on the target etching depth information. For example, a plurality of irregularities existing in a first unit etching area may protrude upwards by an average of 50 nm with respect to a reference vertical level, and a plurality of irregularities existing in a second unit etching area may protrude upwards by an average of 20 nm with respect to the reference vertical level. In this case, the controller 300 may identify the first target etching depth for the first unit etching area as 50 nm and the second target etching depth for the second unit etching area as 20 nm, based on the target etching depth information.

Subsequently, in the second operation (S1200), the local etching apparatus 10 may identify a plurality of light modulation values respectively corresponding to the plurality of unit etching areas, based on the plurality of target etching depths (S1220).

The plurality of unit etching areas may respectively correspond to the plurality of light modulation pixels of the spatial light modulator 230. In the inventive concept, the expression “a certain unit etching area corresponds to a certain light modulation pixel” may have the same meaning as “light output from a certain light modulation pixel reaches a certain unit etching area.”

The plurality of light modulation values may be respectively assigned to the plurality of light modulation pixels of the spatial light modulator 230. In the inventive concept, “a plurality of light modulation values” may refer to values respectively assigned to the plurality of light modulation pixels of the spatial light modulator 230 to modulate the light intensity distribution of the second pulsed laser light PL2 to a target light intensity distribution. As described above with reference to FIG. 3, the light modulation value may be a direction and intensity value of an electric field applied to the light modulation pixel. However, the light modulation value is not limited to the direction and intensity value of the electric field applied to the light modulation pixel, and may also be implemented as various types of control values depending on a driving principle of the spatial light modulator 230.

The method of the controller 300 identifying a plurality of light modulation values respectively corresponding to the plurality of unit etching areas is described in detail with reference to FIGS. 6 to 9 below.

FIG. 6 is a cross-sectional view illustrating the etching region EA according to an embodiment.

Referring to FIG. 6, the etching region EA may include a plurality of points, i.e., first to third points, 31, 32, and 33. Referring to FIG. 6, the target etching depth distribution for the etching region EA is described based on only the first point 31, the second point 32, and the third point 33 included in the etching region EA.

The first point 31 may be a point protruding upward from a reference vertical level RL by a first thickness h1, the second point 32 may be a point protruding upward from the reference vertical level RL by a second thickness h2, and the third point 33 may be a point that does not protrude from the reference vertical level RL. Here, the reference vertical level RL may refer to a target etching depth of the local etching apparatus 10. For example, the local etching apparatus 10 may perform a local etching process such that the entire region of the upper surface 400ts of the target 400 is etched to the reference vertical level RL. For example, the reference vertical level RL may be set to the lowest vertical level among a plurality of vertical levels of the upper surface 400ts of the target 400.

According to an embodiment, the controller 300 may identify a target etching depth distribution for the etching region EA, based on target etching depth information. The controller 300 may identify the target etching depths respectively for the plurality of points included in the etching region EA. For example, the controller 300 may identify the target etching depth for the first point 31 as the first thickness h1, the target etching depth for the second point 32 as the second thickness h2, greater than the first thickness h1, and the target etching depth for the third point 33 as “0”.

According to an embodiment, the controller 300 may identify the target light intensity distribution for the etching region EA, based on a target etching depth distribution. The target light intensity distribution may include the target light intensities respectively for the plurality of points included in the etching region EA. For example, the controller 300 may identify the target light intensity for the first point 31 as a first light intensity (e.g., 10 W/cm²), the target light intensity for the second point 32 as a second light intensity (e.g., 14 W/cm²), greater than the first light intensity, and the target light intensity for the third point 33 as a third light intensity (e.g., 1 W/cm²), less than the first light intensity.

In general, the etching region EA may be a region having an average diameter of several mm to several tens of mm, and as described above, the plurality of points 31, 32, and 33 included in the etching region EA may be arranged at different vertical levels, respectively. Therefore, when performing a local etching process, etching rates need to be set to be different respectively for the plurality of points 31, 32, and 33. To this end, reducing the diameter of the etching region EA may degrade throughput of the local etching process. However, the local etching apparatus 10 according to one or more embodiments may set the etching rates respectively for the plurality of points 31, 32, and 33 to be different from each other by projecting beams of region-heating light HL having different light intensities respectively to the plurality of points 31, 32, and 33 included in the etching region EA. Referring to FIGS. 7 to 9, a method of the local etching apparatus 10 projecting beams of region-heating light HL having different light intensities respectively to the plurality of points 31, 32, and 33 is described in detail.

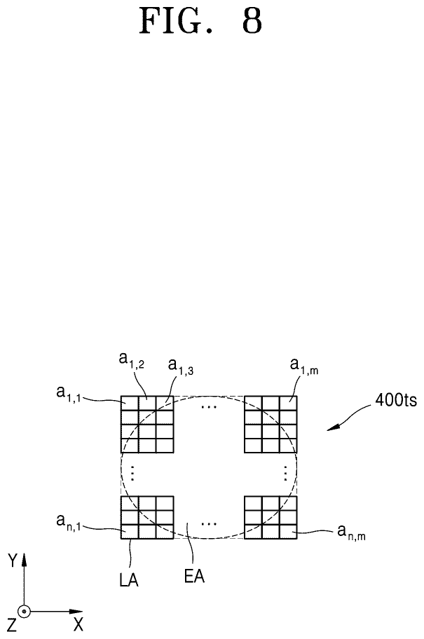

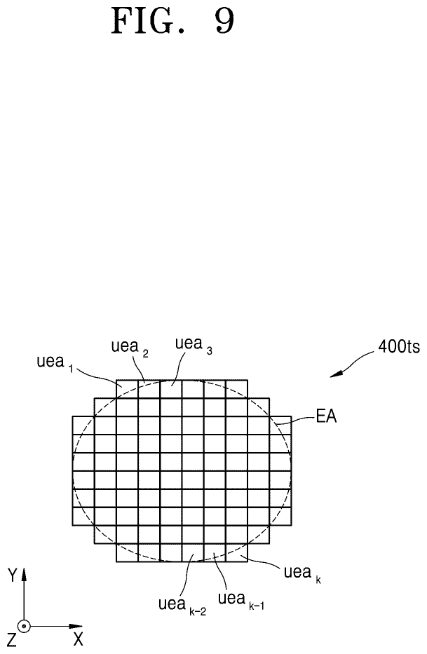

FIG. 7 is a cross-sectional view illustrating the spatial light modulator 230 according to an embodiment. FIG. 8 is a cross-sectional view illustrating the etching region EA and the light projection region LA, according to an embodiment. FIG. 9 is a cross-sectional view illustrating the etching region EA according to an embodiment. FIGS. 8 and 9 are top views of the upper surface 400ts of the target 400.

Referring to FIG. 7, the spatial light modulator 230 may include the plurality of light modulation pixels p_{1,1}, p_{1,2}, . . . , p_{n,m}. Referring to FIGS. 8 and 9, the light projection region LA may include a plurality of unit projection areas a_{1,1}, a_{1,2}, . . . , a_{n,m}, and the plurality of unit projection areas a_{1,1}, a_{1,2}, . . . , a_{n,m} may include a plurality of unit etching areas uea₁, uea₂, . . . , ueaₖ.

According to an embodiment, the plurality of unit projection areas a_{1,1}, a_{1,2}, . . . , a_{n,m} may respectively correspond to the plurality of light modulation pixels p_{1,1}, p_{1,2}, . . . , p_{n,m} of the spatial light modulator 230. In other words, the plurality of unit projection areas a_{1,1}, a_{1,2}, . . . , a_{n,m} may respectively correspond to the plurality of light modulation pixels p_{1,1}, p_{1,2}, . . . , p_{n,m}. For example, the region-heating light HL output from the light modulation pixel p_{1,1} of a first row and a first column may be projected onto the unit projection area a_{1,1} of the first row and the first column, and the region-heating light HL output from the light modulation pixel p_{1,2} of the first row and the second column may be projected onto the unit projection area a_{1,2} of the first row and the second column.

In addition, the plurality of unit projection areas a_{1,1}, a_{1,2}, . . . , a_{n,m} may include the plurality of unit etching areas uea₁, uea₂, . . . , ueaₖ and a plurality of unit non-etching areas. Here, the plurality of unit etching areas uea₁, uea₂, . . . , ueaₖ may include a unit projection area that overlaps the etching region EA, among the plurality of unit projection areas a_{1,1}, a_{1,2}, . . . , a_{n,m}. Meanwhile, the plurality of unit non-etching areas may include a unit projection area that does not overlap the etching region EA, among the plurality of unit projection areas a_{1,1}, a_{1,2}, . . . , a_{n,m}. For example, as illustrated in FIG. 8, the unit projection area a_{1,1} of the first row and the first column does not overlap the etching region EA, so the unit projection area a_{1,1} of the first row and the first column may be a unit non-etching area. Meanwhile, a portion of the unit projection area a_{1,3} of the first row and third column overlaps the etching region EA, so the unit projection area a_{1,3} of the first row and third column may be a unit etching area.

Here, the plurality of unit projection areas a_{1,1}, a_{1,2}, . . . , a_{n,m} and the plurality of unit etching areas uea₁, uea₂, . . . , ueaₖ may refer to virtual unit areas identified by the controller 300. In an embodiment, the controller 300 may divide the light projection region LA into the plurality of unit projection areas a_{1,1}, a_{1,2}, . . . , a_{n,m} based on the arrangement structure of the plurality of light modulation pixels p_{1,1}, p_{1,2}, . . . , p_{n,m} included in the spatial light modulator 230 and the arrangement position and structure of the projection optical system 250 that projects the region-heating light HL output from the spatial light modulator 230 onto the upper surface 400ts of the target 400. In addition, the controller 300 may identify unit projection areas overlapping the etching region EA among the plurality of unit projection areas a_{1,1}, a_{1,2}, . . . , a_{n,m} and identify the identified unit projection areas as the plurality of unit etching areas uea₁, uea₂, . . . , ueaₖ.

Depending on the arrangement position and arrangement structure of the projection optical system 250, pixel pitches of the plurality of light modulation pixels p_{1,1}, p_{1,2}, . . . , p_{n,m} may be the same as pitches of the plurality of unit etching areas uea₁, uea₂, . . . , ueaₖ, or the pitches of the plurality of unit etching areas uea₁, uea₂, . . . , ueaₖ may be greater or less than the pixel pitches of the plurality of light modulation pixels p_{1,1}, p_{1,2}, . . . , p_{n,m}.

The controller 300 may identify a plurality of target etching depths respectively for the plurality of unit etching areas uea₁, uea₂, . . . , ueaₖ included in the etching region EA, based on the target etching depth information. In addition, the controller 300 may identify a plurality of light modulation values respectively corresponding to the plurality of unit etching areas uea₁, uea₂, . . . , ueaₖ based on the plurality of target etching depths respectively for the plurality of unit etching areas uea₁, uea₂, . . . , ueaₖ.

According to an embodiment, the controller 300 may identify a plurality of target light intensities respectively for the plurality of unit etching areas uea₁, uea₂, . . . , ueaₖ, based on the target etching depths respectively for the plurality of unit etching areas uea₁, uea₂, . . . , ueaₖ included in the etching region EA. For example, the target etching depth distribution may include information indicating that a target etching depth for the first unit etching area uea₁ is a first etching depth, and a target etching depth for the second unit etching area uea₂ is a second etching depth which is greater than the first etching depth. In this case, the controller 300 may set the second target light intensity for the second unit etching area uea₂ to a greater light intensity than the first target light intensity for the first unit etching area uea₁. In addition, as described above with reference to FIG. 4, the controller 300 may set a target light intensity for a plurality of unit non-etching areas (e.g., the unit projection area a_{1,1} of the first row and the first column) that does not overlap the etching region EA to 0.

According to an embodiment, the controller 300 may identify a plurality of light modulation values, based on a plurality of target light intensities respectively for the plurality of unit etching areas uea₁, uea₂, . . . , ueaₖ. For example, the controller 300 may store an algorithm that calculates the “light modulation value” required to project the region-heating light HL having a “certain target light intensity” onto a “certain unit etching area.” In an embodiment, in order to project the region-heating light HL having the first target light intensity to the first unit etching area uea₁, a first light modulation value may be assigned to one light modulation pixel corresponding to the first unit etching area uea₁. In addition, in order to project the region-heating light HL having the second target light intensity to the second unit etching area uea₂, a second light modulation value that is different from the first light modulation value may be assigned to one light modulation pixel corresponding to the second unit etching area uea₂. The controller 300 may identify the plurality of light modulation values respectively corresponding to the plurality of target light intensities by inputting each of the plurality of target light intensities into the algorithm.

However, the aforementioned example merely illustrates a method in which the controller 300 identifies the plurality of light modulation values respectively corresponding to the plurality of target light intensities, based on the certain algorithm, and the controller 300 may also identify each of the plurality of light modulation values based on various methods (e.g., machine learning, look-up table, etc.).

The controller 300 may also identify each of the plurality of light modulation values such that the light quantity of region-heating light HL projected onto the unit etching area of the first target etching depth has a greater value than the light quantity of region-heating light HL projected onto the unit etching area of the second target etching depth that is greater than the first target etching depth.

The controller 300 may assign the plurality of identified light modulation values respectively to the plurality of light modulation pixels p_{1,1}, p_{1,2}, . . . , p_{n,m} of the spatial light modulator 230. The plurality of light modulation pixels p_{1,1}, p_{1,2}, . . . , p_{n,m} to which the plurality of light modulation values are respectively assigned may respectively modulate the second pulsed laser light PL2 incident on each of the plurality of light modulation pixels p_{1,1}, p_{1,2}, . . . , p_{n,m} to output the region-heating light HL.

As illustrated in FIG. 9, the plurality of unit etching areas uea₁, uea₂, . . . , ueaₖ may include k unit etching areas (k is a natural number greater than or equal to 10). In this case, the controller 300 may set target heating degrees respectively for the k unit etching areas to be different by setting the target light intensities respectively for the k unit etching areas to different values. In some embodiments, the controller 300 may of course set the same target light intensity for some of the k unit etching areas.

Although FIGS. 8 and 9 illustrate that each of the plurality of unit projection areas a_{1,1}, a_{1,2}, . . . , a_{n,m} and the plurality of unit etching areas uea₁, uea₂, . . . , ueaₖ is shown as a single independent unit area, this is only an example. Among the plurality of unit projection areas a_{1,1}, a_{1,2}, . . . , a_{n,m}, adjacent unit projection areas may have some overlapping region. In addition, among the plurality of unit etching areas uea₁, uea₂, . . . , ueaₖ, adjacent unit etching areas may have some overlapping regions.

The width of the plurality of unit etching areas uea₁, uea₂, . . . , ueaₖ may be determined based on a pixel width of the plurality of light modulation pixels p_{1,1}, p_{1,2}, . . . , p_{n,m} and the arrangement position and the arrangement structure of the projection optical system 250. For example, the width of the plurality of unit etching areas uea₁, uea₂, . . . , ueaₖ may be implemented as hundreds of nm² to hundreds of mm². The width of the plurality of unit etching areas uea₁, uea₂, . . . , ueaₖ may be implemented in units of nm² to mm², and the local etching apparatus 10 may set the etching rates of plasma particles PL respectively for the plurality of unit etching areas uea₁, uea₂, . . . , ueaₖ to be different by varying the heating degrees by the region-heating light HL respectively for the plurality of unit etching areas uea₁, uea₂, . . . , ueaₖ. In other words, spatial resolution of the local etching process performed by the local etching apparatus 10 may be improved to the units of nm² to mm².

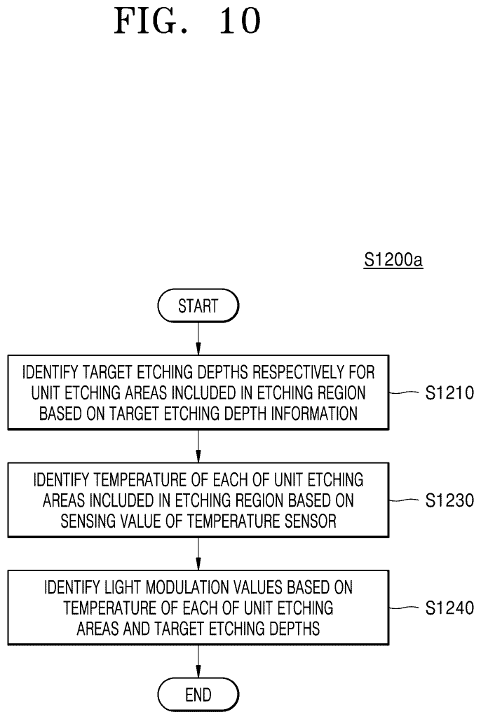

FIG. 10 is a flowchart illustrating a local etching method of the local etching apparatus 10, according to an embodiment.

Referring to FIG. 10, in a second operation (S1200a), the local etching apparatus 10 may identify a plurality of target etching depths respectively for the plurality of unit etching areas included in the etching region EA, based on the target etching depth information (S1210).

Next, in the second operation (S1200a), the local etching apparatus 10 may identify a temperature of each of the plurality of unit etching areas included in the etching region EA, based on a sensing value of a temperature sensor (S1230).

Subsequently, in the second operation (S1200a), the local etching apparatus 10 may identify a plurality of light modulation values based on the respective temperatures of the plurality of unit etching areas and the plurality of target etching depths (S1240).

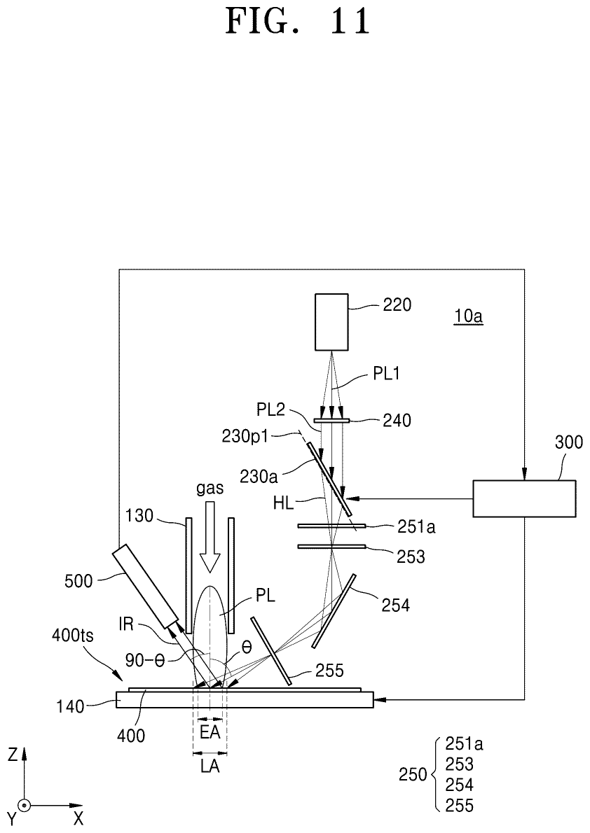

The operation of the local etching apparatus 10 to identify the plurality of light modulation values based on the sensing value of the temperature sensor is described in detail with reference to FIG. 11 below.

FIG. 11 is a cross-sectional view illustrating a local etching apparatus 10a according to an embodiment. In the description of FIG. 11, the same descriptions as those given above with reference to FIGS. 1 and 2 are omitted and differences from the local etching apparatus 10 of FIGS. 1 and 2 are mainly described.

The local etching apparatus 10a may include a spatial light modulator 230a, the projection optical system 250, and a temperature sensor 500.

The spatial light modulator 230a of FIG. 11 may be a transmissive spatial light modulator (transmissive SLM), unlike the spatial light modulator 230 of FIGS. 1 and 3. The spatial light modulator 230a may modulate the second pulsed laser light PL2 to output the region-heating light HL. The method of the spatial light modulator 230a modulating the second pulsed laser light PL2 is the same as the light modulation method described above, so a description thereof is omitted.

The projection optical system 250 may project the region-heating light HL output from the spatial light modulator 230a onto the light projection region LA. The projection optical system 250 may include a polarizer 251a, at least one first lens 253, a mirror 254, and at least one second lens 255 arranged in a traveling path of the region-heating light HL.

According to an embodiment, the projection optical system 250 may project the region-heating light HL such that a shape of an image formed by the region-heating light HL on an SLM plane 230p1 is identical to a shape of an image formed by the region-heating light HL on the upper surface 400ts of the target 400. As illustrated in FIG. 11, when the spatial light modulator 230a is a transmissive spatial light modulator, the SLM plane 230pl may exist on the backside of the spatial light modulator 230a and may be a virtual plane parallel to the spatial light modulator 230a.

According to another embodiment, the projection optical system 250 may appropriately magnify the region-heating light HL and project the same onto the light projection region LA. In this case, the image formed by the region-heating light HL on the SLM plane 230p may be smaller than the image formed by the region-heating light HL on the upper surface 400ts.

In order to ensure that the image formed on the upper surface 400ts of the target 400 has the shape corresponding to the image formed on the SLM plane 230p, the position of at least one first lens 253 and the position of at least one second lens 255 of the projection optical system 250 may be symmetrical with respect to an optical axis of the mirror 254. In addition, the mirror 254 of the projection optical system 250 and the spatial light modulator 230a may be positioned to be symmetrical with respect to the at least one first lens 253. For example, the spatial light modulator 230a and the mirror 254 may be arranged to be inclined with respect to the vertical direction (the Z direction), and at least one first lens 253 may be arranged parallel to the horizontal directions (X and Y directions).

The temperature sensor 500 may sense the temperature of each of the plurality of unit etching areas included in the etching region EA based on the light quantity of light emitted from the etching region EA. The light emitted from the etching region EA may include light reflected from the etching region EA and light emitted from the etching region EA.

For example, the temperature sensor 500 may assume that the upper surface 400ts of the target 400 is a black body and may sense the temperature of each of the plurality of unit etching areas, based on the light quantity of light emitted from the etching region EA.

The temperature sensor 500 may receive light traveling along a path perpendicular to the traveling path of the region-heating light HL incident on the upper surface 400ts. For example, as illustrated in FIG. 11, when the region-heating light HL is incident on the upper surface 400ts at an angle θ with respect to the vertical direction, the temperature sensor 500 may receive light traveling at an angle of “90-θ” with respect to the vertical direction.

The controller 300 may identify a target temperature for each of the plurality of unit etching areas, based on the plurality of target etching depths.

According to an embodiment, the controller 300 may set a high target temperature for a unit etching area having a high target etching depth among the plurality of unit etching areas and may set a relatively low target temperature for a unit etching area having a low target etching depth. For example, the controller 300 may identify a target temperature of a unit etching area of a first target etching depth as a first target temperature (e.g., 380 K), and a target temperature of a unit etching area of a second target etching depth that is lower than the first target etching depth as a second target temperature (e.g., 300 K) that is lower than the first target temperature.

Once the target temperature of each of the plurality of unit etching areas is identified, the controller 300 may identify a target light intensity distribution for heating each of the plurality of unit etching areas to the target temperature. The controller 300 may control the spatial light modulator 230a such that the region-heating light HL having a target light intensity distribution may be projected onto the etching region EA.

According to an embodiment, the controller 300 may obtain temperature values respectively for the plurality of unit etching areas from the temperature sensor 500. The controller 300 may identify a plurality of light modulation values, based on a difference between the temperature values respectively for the plurality of unit etching areas obtained from the temperature sensor 500 and the target temperature of each of the plurality of unit etching areas.

In an embodiment, in case that the temperature of any one unit etching area is lower than the target temperature of the any one unit etching area, the controller 300 may identify a light modulation value to cause a high light intensity of region-heating light HL to be projected to the any one unit etching area. Conversely, in case that the temperature of any one unit etching area is higher than the target temperature of the any one unit etching area, the controller 300 may identify a light modulation value to cause a low light intensity of region-heating light HL to be projected to the any one unit etching area.

As described above, the controller 300 may also feedback-control the spatial light modulator 230a, based on the temperature sensing value obtained from the temperature sensor 500. Through this, the local etching process performed by the local etching apparatus 10a may be performed more precisely.

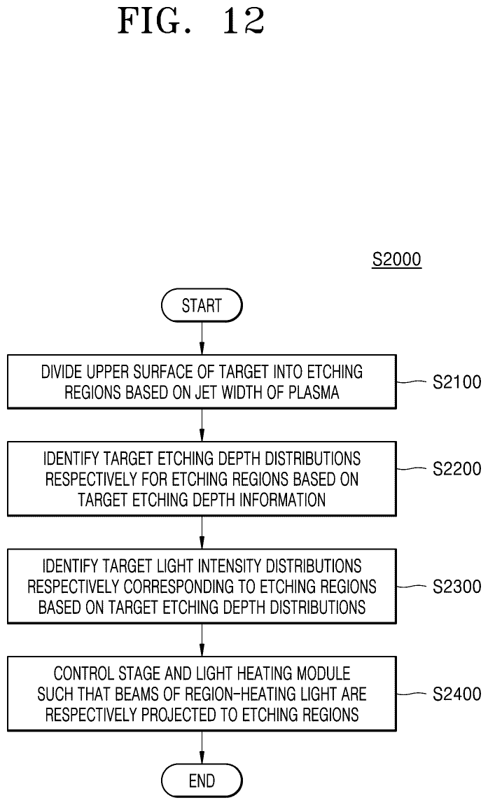

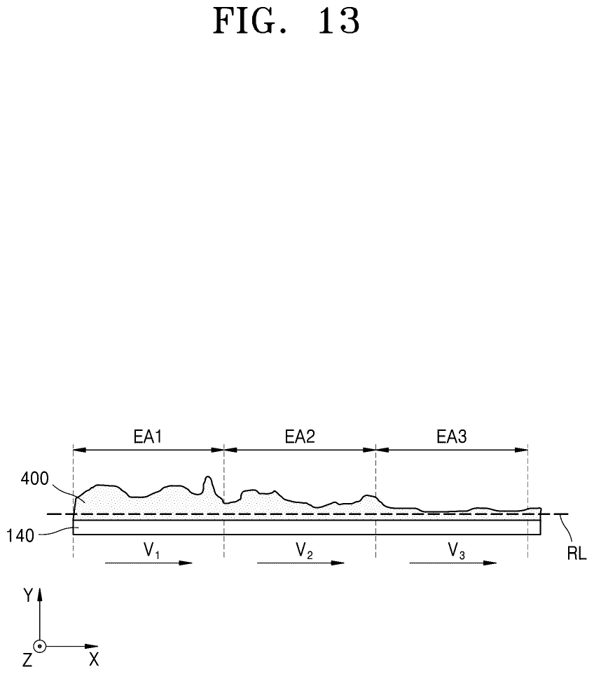

FIG. 12 is a flowchart illustrating a local etching method (S2000) of the local etching apparatus 10, according to an embodiment. FIG. 13 is a cross-sectional view of the target 400 according to an embodiment. Descriptions are given with reference to FIGS. 12 and 13 together with FIGS. 1 and 3.

Referring to FIG. 12, the local etching apparatus 10 may divide the upper surface 400ts of the target 400 into a plurality of etching regions, i.e., first, second, and third etching regions EA1, EA2, and EA3, based on a jet width of plasma (S2100).

Here, the jet width of the plasma may be equal to the width of the etching region EA of FIG. 3. The controller 300 may divide the upper surface 400ts of the target 400 into the plurality of etching regions EA1, EA2, and EA3, based on the total area of the upper surface 400ts of the target 400 and the jet width of the plasma. For example, as illustrated in FIG. 13, the upper surface 400ts of the target 400 may include the first etching region EA1, the second etching region EA2, and the third etching region EA3. In the above, it is only described that the upper surface 400ts of the target 400 may be divided into three etching regions, but this is only for convenience of description, and the upper surface 400ts of the target 400 may be divided into tens to hundreds of etching regions when an etching process is performed.

Subsequently, the local etching apparatus 10 may identify a plurality of target etching depth distributions respectively for the plurality of etching regions EA1, EA2, and EA3, based on the target etching depth information (S2200). For example, the controller 300 may identify a first target etching depth distribution for the first etching region EA1 by extracting only the target etching depth information for the first etching region EA1 from the target etching depth information, and may identify a second target etching depth distribution for the second etching region EA2 by extracting only the target etching depth information for the second etching region EA2. The method of the controller 300 identifying the target etching depth distribution for the etching region has been described above, so a detailed description is omitted.

Subsequently, the local etching apparatus 10 may identify the plurality of target light intensity distributions respectively corresponding to the plurality of etching regions EA1, EA2, and EA3, based on the respective, plurality of target etching depth distributions for the plurality of etching regions EA1, EA2, and EA3 (S2300).

For example, the controller 300 may identify a first target light intensity distribution for the first etching region EA1, based on a first target etching depth distribution for the first etching region EA1, and may identify a second target light intensity distribution for the second etching region EA2 based on a second target etching depth distribution for the second etching region EA2. The method of the controller 300 identifying the target light intensity distribution based on the target etching depth distribution has been described above, so a detailed description is omitted.

According to an embodiment, the controller 300 may identify a plurality of target light intensity distributions respectively corresponding to the plurality of etching regions EA1, EA2, and EA3, based on the plurality of target etching depth distributions and region-specific driving speed information of the target 400 by the stage 140.

The region-specific driving speed information may refer to a profile of a horizontal driving speed of the target 400. In an embodiment, the region-specific driving speed information may include horizontal driving speed information corresponding to each of the plurality of etching regions EA1, EA2, and EA3. The horizontal driving speed information corresponding to each of the plurality of etching regions EA1, EA2, and EA3 may be determined based on an average protrusion degree with respect to the reference vertical level RL of each of the plurality of etching regions EA1, EA2, and EA3.

For example, the first etching region EA1 may protrude upward significantly with respect to the reference vertical level RL, and the third etching region EA3 may protrude upward relatively less with respect to the reference vertical level RL. In this case, the region-specific driving speed information may include information, such as “Drive the target 400 at a first speed V₁ if the spray port 130sp of the plasma nozzle 130 faces the first etching region EA1 and drive the target 400 at a third speed V₃ that is faster than the first speed V₁ if the spray port 130sp faces the third etching region EA3.”

The controller 300 may identify the target light intensity distributions respectively corresponding to the plurality of etching regions EA1, EA2, and EA3 by considering even the region-specific driving speed information. For example, a horizontal driving speed for the third etching region EA3 may be the third speed V₃, which is a very fast speed. In this case, the time for heating each of the plurality of unit etching areas included in the third etching region EA3 may be very short. Meanwhile, the horizontal driving speed for the first etching region EA1 may be the first speed V₁ that is slower than the third speed V₃. In this case, the time for heating each of the plurality of unit etching areas included in the first etching region EA1 may be relatively long. Accordingly, the controller 300 may set a light intensity average value or median value of the first target light intensity distribution for the first etching region EA1 to a smaller value than a light intensity average value or median value of the third target light intensity distribution for the third etching region EA3. Alternatively, the controller 300 may set a light intensity variation of the first target light intensity distribution to a smaller value than a light intensity variation of the third target light intensity distribution. However, the method of the controller 300 identifying the target light intensity distributions respectively corresponding to the plurality of etching regions EA1, EA2, and EA3 based on the region-specific driving speed information is not limited to the example described above, and the target light intensity distributions respectively corresponding to the plurality of etching regions EA1, EA2, and EA3 may be identified based on various methods.

Subsequently, the local etching apparatus 10 may control the stage 140 and the light heating module 200 such that a plurality of beams of region-heating light are respectively projected to the plurality of etching regions EA1, EA2, and EA3 (S2400). Here, the plurality of beams of region-heating light may be beams of region-heating light respectively having target light intensity distributions respectively corresponding to the plurality of etching regions EA1, EA2, and EA3.

The controller 300 may control the stage 140 such that the target 400 is driven in the horizontal direction, based on the region-specific driving speed information. While the target 400 is driven in the horizontal direction, the controller 300 may control the spatial light modulator 230 such that the plurality of beams of region-heating light are respectively projected onto the plurality of etching regions EA1, EA2, and EA3. For example, when the spray port 130sp faces the first etching region EA1, the controller 300 may assign a plurality of light modulation values respectively to the plurality of light modulation pixels of the spatial light modulator 230 to project region-heating light having a first target light intensity distribution onto the first etching region EA1. Subsequently, when the region the spray port 130sp faces is changed to the second etching region EA2 by driving the stage 140, the controller 300 may assign a plurality of light modulation values respectively to the plurality of light modulation pixels of the spatial light modulator 230 in order to project region-heating light having a second target light intensity distribution onto the second etching region EA2.

The local etching apparatus 10 may perform a local etching process on the entire region of the upper surface 400ts of the target 400 through the method described above with reference to FIGS. 12 and 13. Accordingly, the local etching apparatus 10 may form a uniform surface over the entire region of the upper surface 400ts of the target 400.

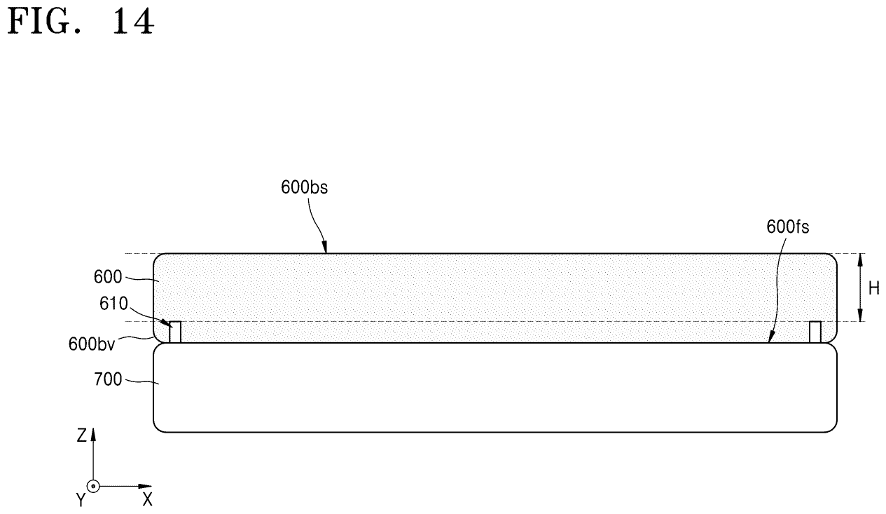

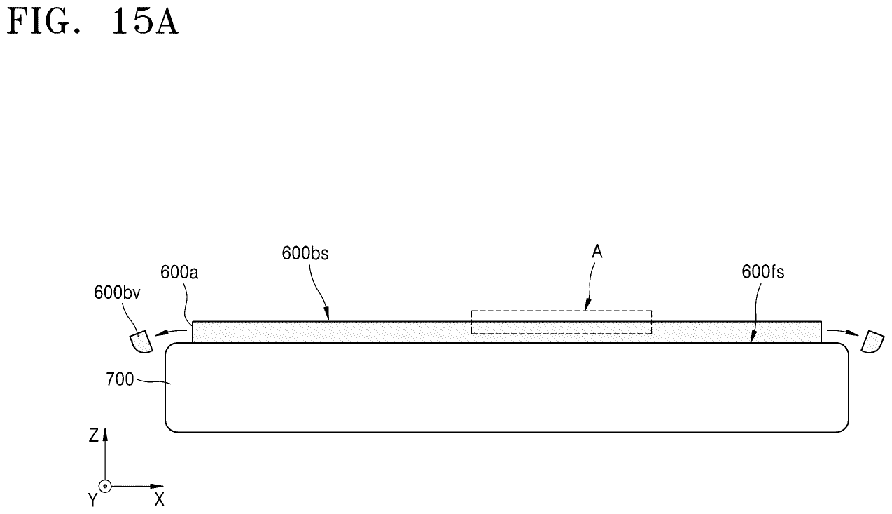

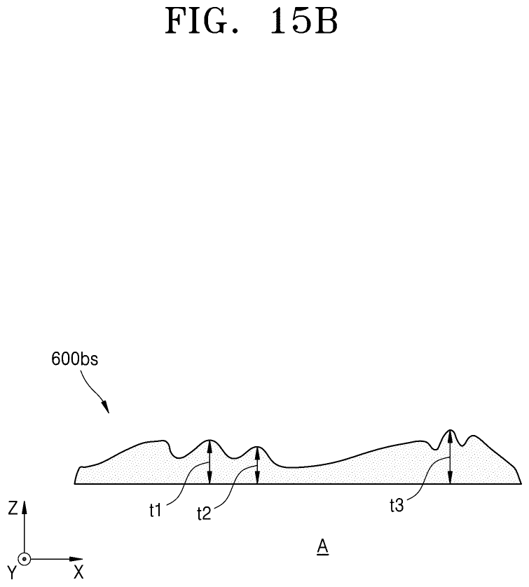

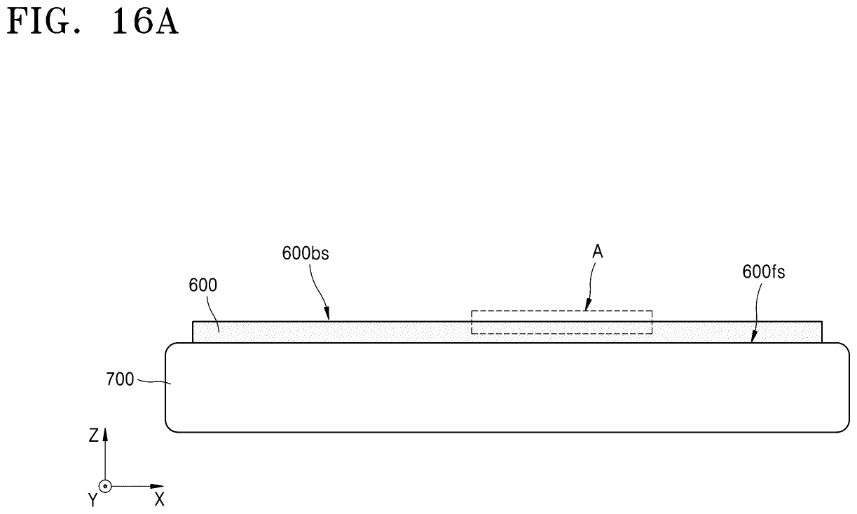

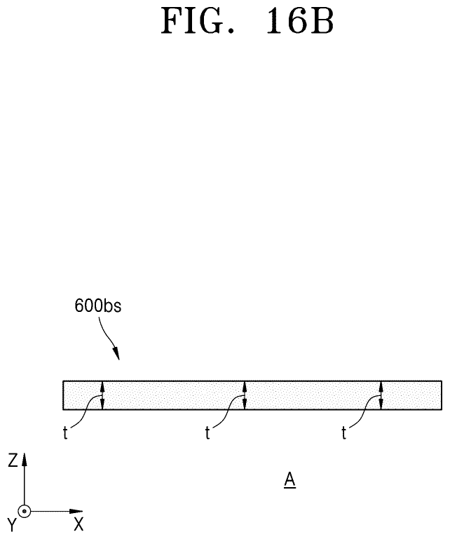

FIGS. 14 to 16B are cross-sectional views illustrating a wafer manufacturing method of the local etching apparatus 10, according to an embodiment.

Referring to FIG. 14, a wafer 600 may be attached on a support wafer 700.

The support wafer 700 may be referred to as a sustain wafer or a carrier wafer. The support wafer 700 may include silicon (e.g., a blank device wafer), soda lime glass, borosilicate glass, silicon carbide, silicon germanium, silicon nitride, gallium arsenide, sapphire, and various metals and ceramics. However, the support wafer 700 is not limited to the examples described above.

The wafer 600 may include a semiconductor, such as silicon (Si) or germanium (Ge), or a compound semiconductor, such as SiGe, SiC, GaAs, InAs, or InP. A front surface 600fs of the wafer 600 may be an active surface on which a semiconductor device is formed. The wafer 600 may be placed such that the front surface 600fs faces the support wafer 700 and a back surface 600bs of the wafer 600 faces the opposite direction of the support wafer 700.

The wafer 600 may be attached to the support wafer 700 by a bonding agent. The bonding agent may be a general adhesive containing a polysiloxane-based compound and may bond the wafer 600 to the support wafer 700 with sufficient strength. However, the method of combining the wafer 600 to the support wafer 700 is not limited to the example described above.

According to an embodiment, the wafer 600 may include a cut portion 610 formed at an edge of the wafer 600. The cut portion 610 may be formed in a circumferential direction at the edge of the wafer 600 with respect to the center of the wafer 600. A vertical distance between an upper surface of the cut portion 610 and the back surface 600bs may be apart by a wafer thinning thickness H. However, the aforementioned example is only an example, and the wafer 600 may not include the cut portion 610.

Referring to FIG. 15A, a wafer thinning process may be performed on the wafer 600. The wafer thinning process may refer to a process of reducing the overall thickness of the wafer 600.

According to an embodiment, through the wafer thinning process, the overall thickness of the wafer 600a may be reduced by the wafer thinning thickness H compared to the overall thickness of the wafer 600 of FIG. 14. In this case, due to the performance of the wafer thinning process, an edge region 600bv may be removed from the wafer 600a.

The wafer thinning process may include at least one of a grinding process, a wet etch process, and a polishing process. For example, the wafer thinning process may include a grinding process and a polishing process performed after the grinding process. As another example, the wafer thinning process may include a grinding process, a wet etching process performed after the grinding process, and a polishing process performed after the wet etching process.

A plurality of irregularities may remain on the surface of the wafer 600a having the overall thickness reduced through the above wafer thinning process. For example, when the wafer thinning process includes a grinding process, an uneven grinding wheel mark may exist on the back surface 600bs of the wafer 600a. As another example, even if the wafer thinning process includes a chemical mechanical polishing process, uneven patterns may be formed on the back surface 600bs of the wafer 600a.

FIG. 15B is an enlarged cross-sectional view of portion “A” of FIG. 15A. Referring to FIG. 15B, a plurality of irregularities may exist on the back surface 600bs of the wafer 600a. For example, a thickness of a first point may be a first thickness t1, a thickness of a second point may be a second thickness t2, and a thickness of a third point may be a third thickness t3. The first thickness t1, the second thickness t2, and the third thickness t3 may all be different.

In general, when a wafer thinning process including a grinding process and a chemical mechanical polishing process is performed, a total thickness variation TTV of the wafer 600a may be 50 nm or more.

Referring to FIG. 16A, a local etching process may be performed on the entire region of the back surface 600bs of the wafer 600.

Here, the description of the local etching process performed on the entire region of the back surface 600bs is the same as the detailed description given above with reference to FIGS. 12 and 13, so a detailed description is omitted. In an embodiment, the local etching process performed on the entire region of the back surface 600bs may be the same as the local etching process performed by the local etching apparatus 10 when the target 400 of FIGS. 12 and 13 is implemented as the wafer 600.

FIG. 16B is an enlarged cross-sectional view of portion “A” of FIG. 16A. Referring to FIG. 16B, the thicknesses of each of the plurality of points existing on the back surface 600bs of the wafer 600 may all be the same as “t”. In some embodiments, there may be a slight difference between the thicknesses of each of the plurality of points.

In an embodiment, as the local etching process by the local etching apparatus 10 is performed on the entire region of the back surface 600bs of the wafer 600, the total thickness variation TTV of the wafer 600 may be 10 nm or less.

As described above, the local etching apparatus 10 according to an embodiment may remove a plurality of fine irregularities existing on the surface of the target, thereby making the surface of the target uniform.

While the inventive concept has been particularly shown and described with reference to embodiments thereof, it will be understood that various changes in form and details may be made therein without departing from the spirit and scope of the following claims.

What is claimed is:

1. A local etching apparatus comprising:
a plasma nozzle jetting plasma particles toward an etching region, which is a portion of an entire region of an upper surface of a target; and
a light heating module projecting a region-heating light toward a light projection region which is a portion of the entire region of the upper surface of the target,
wherein the light heating module includes:
a laser light source outputting a pulsed laser light; and
a spatial light modulator receiving the pulsed laser light, modulating the pulsed laser light, and outputting the region-heating light, and
wherein the light projection region includes the etching region.

2. The local etching apparatus of claim 1,
wherein the spatial light modulator modulates the pulsed laser light to output the region-heating light so that the region-heating light has a target light intensity distribution in the etching region,
wherein the target light intensity distribution is a light intensity distribution corresponding to a target etching depth distribution for the etching region, and
wherein the target etching depth distribution includes a plurality of target etching depths respectively for a plurality of points included in the etching region.

3. The local etching apparatus of claim 2,
wherein the target light intensity distribution comprises a distribution set so that a light quantity of the region-heating light projected on a point of a first target etching depth among the plurality of points, has a greater value than a light quantity of the region-heating light projected on a point of a second target etching depth among the plurality of points, and
wherein the first target etching depth is greater than the second target etching depth.

4. The local etching apparatus of claim 2,
wherein the light projection region is a wider region than the etching region, and
wherein the spatial light modulator modulates the pulsed laser light so that no light quantity of the region-heating light is projected onto a region other than the etching region in the light projection region.

5. The local etching apparatus of claim 1,
wherein the plasma particles are jetted toward the etching region in a vertical direction perpendicular to the upper surface of the target, and
wherein the region-heating light is projected toward the light projection region in a state of being inclined with respect to the vertical direction.

6. The local etching apparatus of claim 1,
wherein the spatial light modulator includes a plurality of light modulating pixels, and
wherein the plurality of light modulation pixels respectively correspond to a plurality of unit etching areas included in the etching region.

7. The local etching apparatus of claim 6, wherein the spatial light modulator assigns a plurality of light modulation values determined based on a plurality of target etching depths respectively corresponding to the plurality of unit etching areas to the plurality of light modulation pixels.

8. The local etching apparatus of claim 1, further comprising a temperature sensor sensing a temperature of the target in the etching region, based on a light quantity of light emitted from the etching region.

9. The local etching apparatus of claim 1, wherein the light heating module further includes:
an illumination optical system transmitting the pulsed laser light from the laser light source to the spatial light modulator, the illumination optical system including at least one lens; and
a projection optical system projecting the region-heating light from the spatial light modulator to the light projection region, the projection optical system including at least one lens,
wherein the projection optical system includes a polarizer located in a traveling path of the region-heating light output from the spatial light modulator.

10. The local etching apparatus of claim 1,
wherein a duration of the pulsed laser light is from several femtoseconds (fs) to several hundreds fs, and
wherein the pulsed laser light includes at least one of ultraviolet (UV) rays, extreme ultraviolet (EUV) rays, X-ray, visible light, and infrared (IR) rays.

11. A local etching apparatus comprising:
a plasma nozzle jetting plasma particles toward an upper surface of a target;
a light heating module projecting a region-heating light toward the upper surface of the target; and
a stage on an upper surface of which the target is placed,
wherein the light heating module includes:
a laser light source; and
a spatial light modulator receiving a pulsed laser light output from the laser light source, modulating the pulsed laser light, and outputting the region-heating light.

12. The local etching apparatus of claim 11, further comprising
a controller configured to store target etching depth information on the upper surface of the target,
wherein the controller is configured to:
identify an etching region, based on position information of the target obtained from the stage,
identify a target light intensity distribution, based on the target etching depth information and the etching region, and
control the spatial light modulator such that the pulsed laser light is modulated into the region-heating light having the target light intensity distribution, and
wherein the etching region is a region in which etching of the target is performed based on the plasma particles and the region-heating light.

13. The local etching apparatus of claim 12, wherein the controller is further configured to:
identify a target etching depth distribution for the etching region, based on the target etching depth information; and
identify the target light intensity distribution for the etching region, based on the target etching depth distribution.

14. The local etching apparatus of claim 12, wherein the controller is further configured to:
identify a plurality of target etching depths respectively for a plurality of unit etching areas included in the etching region, based on the target etching depth information;
identify a plurality of light modulation values respectively corresponding to the plurality of unit etching areas, based on the plurality of target etching depths; and
assign the plurality of light modulation values respectively to a plurality of light modulation pixels included in the spatial light modulator.

15. The local etching apparatus of claim 14,
wherein the controller is further configured to identify each of the plurality of light modulation values so that a light quantity of the region-heating light projected onto a unit etching area of a first target etching depth, among the plurality of unit etching areas, has a greater value than a light quantity of the region-heating light projected onto a unit etching area of a second target etching depth, and
wherein the first target etching depth is greater than the second target etching depth.

16. The local etching apparatus of claim 14, further comprising
a temperature sensor sensing a temperature of each of the plurality of unit etching areas included in the etching region, based on a light quantity of light emitted from the etching region,
wherein the controller is further configured to:
identify a temperature of each of the plurality of unit etching areas, based on a sensing value of the temperature sensor; and
identify the plurality of light modulation values, based on the respective temperatures of the plurality of unit etching areas and the plurality of target etching depths.

17. The local etching apparatus of claim 16, wherein the controller is further configured to:
identify a target temperature of each of the plurality of unit etching areas, based on the plurality of target etching depths; and
identify the plurality of light modulation values, based on a difference between a temperature of each of the plurality of unit etching areas and the target temperature of each of the plurality of unit etching areas.

18. The local etching apparatus of claim 14,
wherein the light heating module further includes a projection optical system projecting the region-heating light from the spatial light modulator to the etching region, the projection optical system including at least one lens, and
wherein the controller is further configured to divide the etching region into the plurality of unit etching areas respectively corresponding to the plurality of light modulation pixels, based on an arrangement structure of the projection optical system.

19. A local etching apparatus comprising:
a plasma nozzle jetting plasma particles toward an upper surface of a target;
a light heating module projecting a region-heating light toward the upper surface of the target;
a stage on an upper surface of which the target is supported, the stage driving the target in a horizontal direction; and
a controller configured to store target etching depth information on the upper surface of the target,
wherein the controller is further configured to:
divide the upper surface of the target into a plurality of etching regions, based on a jet width of the plasma particles,
identify a plurality of target etching depth distributions respectively for the plurality of etching regions, based on the target etching depth information,
identify a plurality of target light intensity distributions respectively corresponding to the plurality of etching regions, based on the plurality of target etching depth distributions, and
control the stage and the light heating module such that a plurality of beams of region-heating light having the plurality of target light intensity distributions respectively corresponding to the plurality of etching regions are projected to the plurality of etching regions, and
wherein each of the plurality of etching regions is a region in which etching of the target is performed by the plurality of beams of region-heating light and the plasma particles.

20. The local etching apparatus of claim 19,
wherein the controller is further configured to further store region-specific driving speed information of the target by the stage, and
wherein the controller is further configured to identify the plurality of target light intensity distributions respectively corresponding to the plurality of etching regions, based on the plurality of target etching depth distributions and the region-specific driving speed information.
